(19) United States
(12) Patent Application Publication
(10) Pub. No.: US 2002/0126034 A1
(43) Pub. Date: Sep. 12, 2002

(54) Tracking analog/digital converter

(76) Inventor: Dieter Draxelmayr, Villach (AT)

Correspondence Address: LERNER AND GREENBERG, P.A., Post Office Box 2480, Hollywood, FL, 33022-2480, US

(21) Appl. No.: 10/094,888

(22) Filed: Mar. 6, 2002

Related U.S. Application Data
(63) Continuation of application No. PCT/DE00/03122, filed on Sep. 5, 2000.

(30) Foreign Application Priority Data
Sep. 6, 1999 (DE) 199 42 450.0

(51) Int. Cl. H03M 1/34

(52) U.S. Cl. 341/164

(57) ABSTRACT

The invention relates to a tracking analog to digital converter that includes a comparator circuit for comparing an analog input signal with an analog reference signal. The comparator circuit emits a comparator output signal and an evaluation circuit is provided for evaluating the comparator output signal. The analog to digital converter includes a counter unit with an adjustable counter increment for emitting a digital counter value. The analog to digital converter also includes a digital to analog converter for converting the digital counter value into the analog reference signal. The evaluation circuit adjusts the counter increment in accordance with the evaluated comparator output signal.

### CROSS-REFERENCE TO RELATED APPLICATION

This application is a continuation of copending International Application No. PCT/DE00/03122, filed Sep. 5, 2000, which designated the United States.

### BACKGROUND OF THE INVENTION

Field of the Invention

The invention relates to a tracking analog/digital converter with automatic step size adjustment.

An analog/digital converter is an electrical circuit which converts an analog input signal to a digital output signal. In sequential analog/digital converters, the bits of the digital word are determined successively. Incremental analog/digital converters compare the analog input voltage with discrete adjustable comparison voltages, which are supplied from a digital/analog converter.

FIG. 1 shows a prior art incremental analog/digital converter. An analog input signal is applied to an input E of the analog/digital converter, and is supplied via a line to a subtractor S. The subtractor S subtracts a comparison voltage from the analog input signal. The comparison voltage is produced by a digital/analog converter DAU. The difference voltage that is produced by the subtractor S is supplied to the non-inverting input of a comparator K. The comparator K compares the analog difference signal that is applied to the non-inverting input with a reference potential, for example ground, and emits a comparator output signal through a comparator output line to a counter Z. The counter Z is a step-up/step-down counter that is clocked by a clock generator T. At its output, the counter Z forms a digital value that is supplied to the digital/analog converter DAU. Together with the step-up/step-down counter Z and the digital/analog converter DAU, the comparator K forms a control loop that minimizes the difference signal at the output of the subtractor S. As soon as an analog input signal is applied to the input E, the step-up/step-down counter Z counts until the analog difference signal at the output of the subtractor S becomes virtually zero. This ensures that the digital output value at the output of the counter Z corresponds to the magnitude of the analog input signal at the input E. The digitized value is then emitted at the output A of the tracking analog/digital converter.

In the prior art tracking analog/digital converter shown in FIG. 1, if the analog input signal changes quickly and/or if the analog input signal has a high amplitude, it takes a long time to convert the analog input signal to the digital output value if the step size of the digital counter is relatively small, and this is disadvantageous. If the step size of the digital counter Z is large, this reduces the resolution of the analog/digital converter. Analog/digital converters have to satisfy various quality criteria, such as a high resolution, a high conversion rate, and low power consumption, and in addition it is desirable to construct the circuits with as little complexity as possible. In this case, one requirement is for an unknown analog input signal to be converted into digital form with a specifically defined percentage accuracy. Analog input signals with a large amplitude can thus be converted with less resolution than analog input signals with a small amplitude. However, since the amplitude and the operating point of the analog input signal are not known in advance, this normally leads to using analog/digital converters that satisfy the requirements in every case for any given analog input signal, so that they are therefore in most cases overdefined for the analog input signal which actually occurs.

### SUMMARY OF THE INVENTION

It is accordingly an object of the invention to provide a tracking analog/digital converter which overcomes the above-mentioned disadvantages of the prior art apparatus of this general type.

In particular, it is an object of the invention to provide a tracking analog/digital converter that has little circuit complexity and that converts an analog input signal, of any signal form, to a digital output value within a short time and with a predetermined resolution accuracy.

With the foregoing and other objects in view there is provided, in accordance with the invention, a tracking analog/digital converter that includes: a comparison circuit for comparing an analog input signal with an analog comparison signal, the comparison circuit emitting a comparator output signal; an evaluation circuit for evaluating the converter output signal; a counter device with an adjustable counter step size for emitting a digital count value; and a digital/analog converter for converting the digital count value to an analog comparison signal. The evaluation circuit sets the counter step size as a function of the comparator output signal that has been evaluated. If the comparator output signal is an essentially constant sequence, the evaluation circuit increases the counter step size. If the comparator output signal is an essentially alternating sequence, the evaluation circuit reduces the counter step size.

In accordance with an added feature of the invention, the comparison circuit includes a subtractor that subtracts the analog comparison signal from the analog input signal and emits an analog difference signal; and the comparison circuit includes a comparator that compares the analog difference signal with a reference potential and emits the comparator output signal.

In accordance with an additional feature of the invention, the comparator output signal is a binary signal sequence.

In accordance with a further feature of the invention, the evaluation circuit has a buffer storage device for storing a data sequence that represents the binary signal sequence.

In accordance with a further added feature of the invention, the buffer storage device is a clocked shift register.

In accordance with a further additional feature of the invention, the evaluation circuit has a logic circuit for logically evaluating the data sequence that is stored in the buffer storage device.

In accordance with yet an added feature of the invention, the evaluation circuit includes a counter step size adjusting device for adjusting the counter step size of the counter device; the logic circuit supplies a logic evaluation signal to the counter step size adjusting device; and the counter step size is adjustable as a function of the logic evaluation signal.

In accordance with yet an additional feature of the invention, the counter step size adjusting device is a step-up/step-down counter which, as a function of the logic evaluation signal, either increases the counter step size, reduces the counter step size, or keeps the counter step size constant.

In accordance with yet a further feature of the invention, the step-up/step-down counter has an overflow protection circuit.

In accordance with yet a further added feature of the invention, the logic circuit includes logic gates having logic inputs that are connected to the buffer storage device.

In accordance with yet a further additional feature of the invention, the counter device has a synchronous step-up/step-down counter with an adjustable step size; and the synchronous step-up/step-down counter includes a plurality of series-connected, controllable counter cells.

In accordance with an added feature of the invention, the counter device has a logic decoding circuit for driving the controllable counter cells as a function of the counter step size.

In accordance with an additional feature of the invention, the logic decoding circuit is a thermometer decoding circuit.

In accordance with another feature of the invention, as a function of the counter step size that has been set, the logic decoding circuit either inhibits the controllable counter cells or allows the controllable counter cells to count.

In accordance with a further feature of the invention, the evaluation circuit has an inhibiting circuit; and the inhibiting circuit, when the counter step size is changed, inhibits any further change to the counter step size for a predetermined number of clock cycles.

The basic idea of the invention is not to keep the step size of the counter device constant, but to vary it as a function of the output signal from the comparator.

In one advantageous refinement of the tracking analog/digital converter, the comparison circuit has a subtractor that subtracts the analog comparison signal from the analog input signal that will be converted and emits an analog difference signal. The comparison circuit also includes a comparator that compares the difference signal with a reference potential and emits the comparator output signal.

The comparator output signal that is emitted from the comparison circuit is preferably a binary signal sequence.

In one preferred embodiment, the evaluation circuit contains a buffer storage device for storing a data sequence from the binary signal sequence. This buffer storage device is preferably a clocked shift register.

In a further preferred embodiment of the tracking analog/digital converter, if the binary signal sequence is essentially constant, the evaluation circuit increases the counter step size of the counter, and if the signal sequence that is emitted from the comparator circuit is essentially alternating, it conversely reduces the counter step size.

The evaluation circuit also preferably contains a logic circuit for logically evaluating the data sequence that is stored in the buffer storage device.

In one preferred development, the evaluation circuit has a counter step size adjusting device for adjusting the counter step size. The counter step size is adjustable as a function of a logic evaluation signal that is emitted from the logic circuit to the counter step size adjusting device.

The logic circuit preferably has logic gates with logic inputs that are connected to the buffer storage device.

In one preferred device, the counter step size adjusting device is a step-up/step-down counter, which increases, reduces, or keeps constant the counter step size of the counter device as a function of the logic evaluation signal. The step-up/step-down counter provided in the evaluation circuit preferably has an overflow protection circuit.

In one preferred development of the tracking analog/digital converter, the counter device has a synchronous step-up/step-down counter with an adjustable step size. This synchronous step-up/step-down counter includes a number of series-connected, controllable counter cells.

In a further preferred development, the counter device with an adjustable step size has a logic decoding circuit for driving the counter cells as a function of the counter step size that has been set. The logic decoding is preferably a thermometer decoding circuit.

In one preferred development, the controllable counter cells are inhibited or allowed to count by the logic decoding circuit as a function of the counter step size that has been set.

Preferred embodiments of the tracking analog/digital converter will be described with reference to the attached drawings in the following text, in order to explain features that are significant to the invention.

Other features which are considered as characteristic for the invention are set forth in the appended claims.

Although the invention is illustrated and described herein as embodied in a tracking analog/digital converter, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 shows a prior art tracking analog/digital converter;

FIG. 2 shows a block diagram of an inventive tracking analog/digital converter;

FIG. 3 shows a block diagram of the evaluation circuit shown in FIG. 2;

FIG. 4 shows a block diagram of the counter device shown in FIG. 2 which has an adjustable step size; and

FIGS. 5A-5C show timing diagrams to explain the method of operation of the tracking analog/digital converter.

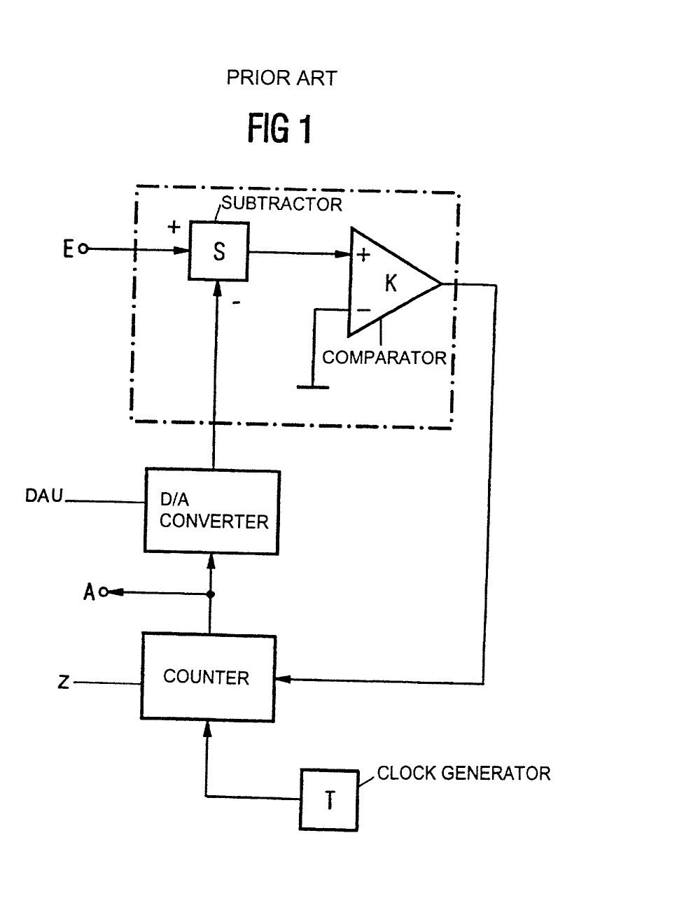

### DESCRIPTION OF THE PREFERRED EMBODIMENTS

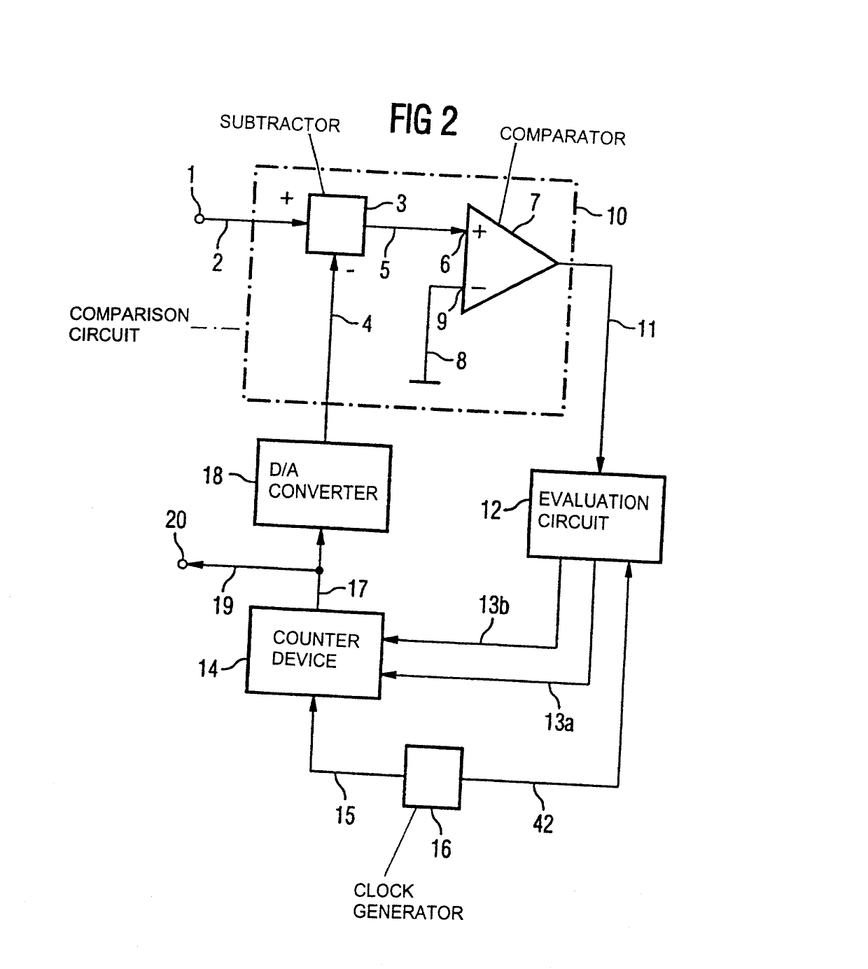

Referring now to the figures of the drawing in detail and first, particularly, to FIG. 2 thereof, there is shown a block diagram of an inventive tracking analog/digital converter. The tracking analog/digital converter has an input connection 1 for receiving an analog signal that will be converted into a digital signal. The input connection 1 is connected, via a line 2, to a subtractor 3. The subtractor 3 subtracts an analog comparison signal that is applied on a line 4 from the analog input signal that is applied on line 2. The subtractor 3 emits the analog difference signal that is formed in this way, via a line 5, to the non-inverting input 6 of a comparator 7. The comparator 7 compares the analog difference signal that is applied to the non-inverting input 6 with a reference potential, which is connected to the inverting input 9 of the comparator 8 via a line 8. The reference potential is preferably ground. The subtractor 3 and the comparator 7 together form a comparison circuit 10 for comparing the analog input signal that is applied to the input connection 1 with a comparison signal that is supplied to the subtractor 3 on the line 4. The comparator 7 in the comparison circuit 10 supplies a comparator output signal to an evaluation circuit 12, via an output line 11. The evaluation circuit 12 evaluates the comparator output signal and supplies a counter step size adjusting signal, via lines 13a, 13b, to a counter device 14 with an adjustable step size. The absolute magnitude of the counter step size is supplied via the adjusting lines 13a of the counter device 14. The mathematical sign of the counter step size is set via a line 13b. The mathematical sign is determined by the evaluation circuit 12 directly from the comparator output signal that is produced on the line 11. When a logic high bit H occurs, a positive step size mathematical sign is set, and conversely, when a logic low bit L occurs, the counter step size mathematical sign is set to be negative. The counter device 14 is supplied with a clock signal, via a clock line 15, from a clock generator 16. The counter device 14 supplies a digital count value, via output lines 17, to a digital/analog converter 18 for converting the digital count value to the analog comparison signal. After the analog/digital conversion, the final digital value produced on the lines 17 is read, via lines 19, at an output connection 20 of the tracking analog/digital converter.

The comparator signal that is emitted from the comparison circuit 10 to the line 11 is a binary signal sequence. If the analog input signal that is applied to the input connection 1 changes quickly, the comparator 7 produces a series of identical decisions, or binary output signals, at its output. The comparator output signal on the line 11 then consists either of a longer sequence of logic low bits L, or a longer sequence of logic high bits H.

If the analog input signal at the connection 1 of the analog/digital converter changes relatively slowly, the digital output value at the output connection 20 of the analog/digital converter oscillates about the exact digital value, so that the binary output signal sequence from the comparator 7 is an alternating sequence of logic low bits L and logic high bits H.

By way of example, a rapidly changing analog input signal results in the following binary signal sequence: Comparator output signal sequence=LLLL . . .

A slowly changing analog input signal results, by way of example, in the following binary comparator output signal sequence: Comparator output signal sequence=LHLHLH . . .

The evaluation circuit 12 logically evaluates the comparator output signal sequence produced on line 11, and depending on the evaluation result, emits a counter step size adjusting signal to the counter 14, via the line 13.

If the binary signal sequence on the line 11 is essentially constant, that is to say if the analog input signal is changing rapidly, the counter step size is increased by the evaluation circuit 12.

If the binary signal sequence on the line 11 is essentially an alternating sequence, that is to say the analog input signal is changing comparatively slowly, the evaluation circuit 12 reduces the counter step size.

The counter step size of the counter device 14 is in this way matched to the analog input signal at the connection 1 of the tracking analog/digital converter.

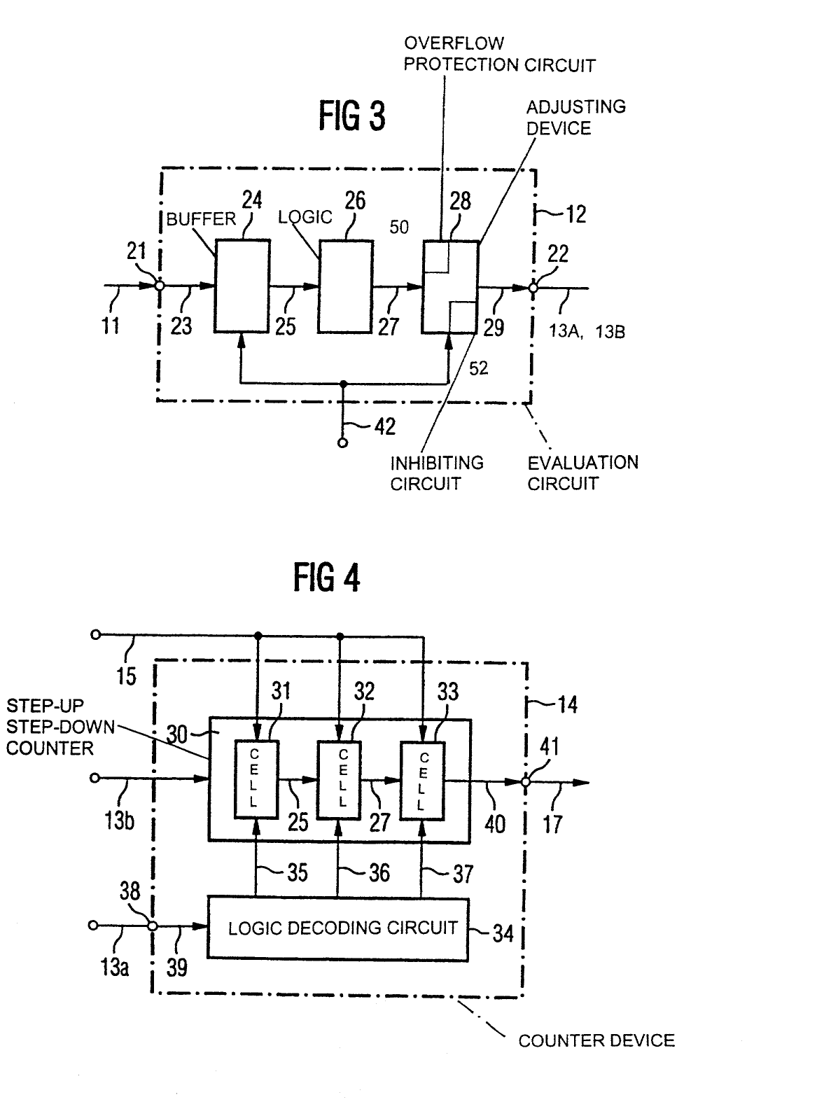

FIG. 3 is a block diagram of the evaluation circuit 12 illustrated in FIG. 2.

The evaluation circuit 12 has an input connection 21, which is connected to the output line 11 from the comparator 7, and an output connection 22, which is connected via the adjusting lines 13a, 13b to the counter device 14. The comparator output signal that is applied to the input connection 21 of the evaluation circuit 12 is passed, via an internal data line 23, to a buffer storage device 24 for storing a data sequence from the applied binary comparator signal sequence. The buffer storage device 24 is preferably a clocked shift register. The data sequence that is buffer-stored in the shift register is read, via lines 25, by a logic circuit 26 for logic evaluation. The logic circuit 26 preferably includes logic gates having logic inputs that are connected to the buffer storage device 24, via the lines 25. The logic circuit 26 produces a logic evaluation signal that is supplied via lines 27 to a counter step size adjusting device 28. The counter step size adjusting device 28 sets the counter step size as a function of the logic evaluation signal that is produced by the logic circuit 26. The counter step size adjusting device 28 is preferably a step-up/step-down counter, which increases the counter step size, decreases the counter step size, or keeps the counter step size constant as a function of the logic evaluation signal. In this case, the step-up/step-down counter preferably has an overflow protection circuit 50, for protecting against counter overflow and counter underrun.

Since, when the counter step size is changed, it is not certain that the next comparator decision will actually directly reflect the effectiveness of this measure, an existing inhibiting circuit 52, which inhibits any further step size change for a certain number of clock cycles, is activated when a step size change is carried out. In one preferred embodiment, one bit of the applied data sequence is, for this purpose, stored in inverted form, so that the data sequence is changed such that its logic evaluation does not initiate a step size change. A new logic evaluation signal to change the step size cannot be produced until a new data sequence has been loaded in the shift register. The counter step size which is set by the counter step size adjusting device 28 is emitted to the counter device 14 via lines 29, the output connection 22 and the adjusting lines 13a, 13b. The evaluation circuit 12 is clocked by the clock generator 16, via a clock line 42.

FIG. 4 shows a block diagram of the counter device 14 for the tracking analog/digital converter shown in FIG. 2. The counter device 14 with an adjustable step size preferably includes a synchronous step-up/step-down counter 30 with a number of series-connected controllable counter cells 31, 32, 33. There may be any desired number of series-connected controllable counter cells 31, 32, 33. The counter device 14 also has a logic decoding circuit 34 that drives the counter cells 31, 32, 33 via control lines 35, 36, 37. The logic decoding circuit 34 is preferably a thermometer decoding circuit. The counter device 14 has an input connection 38 that is connected to the logic decoding circuit 34 via an internal line 39. The logic decoding circuit 34 preferably includes a number of combinational logic gates. The counter step size that has been set is supplied to the logic decoding circuit 34, and is decoded, via the adjusting line 13, the input connection 38 and the internal line 39. Using the drive line 35, 36, 37, the logic decoding circuit 34 either inhibits or allows the controllable counter cells 31, 32, 33 to count. The control command indicates to the counter cell whether it should itself carry out a counting process or whether, although it should not itself count, it should nevertheless pass on any counting command to the next downstream counter cell. For this purpose, each controllable counter cell 31, 32, 33 has a first gate which controls whether that counter cell will or will not count, and further gates which control whether the counter cell is an active component of the synchronous step-up/step-down counter 30, or whether any counting commands should just be passed on from that counter cell to the next counter cell.

The digital output value from the synchronous step-up/step-down counter 30 within the counting device 14 is emitted via internal output lines 40 and output connections 41 to the output lines 17.

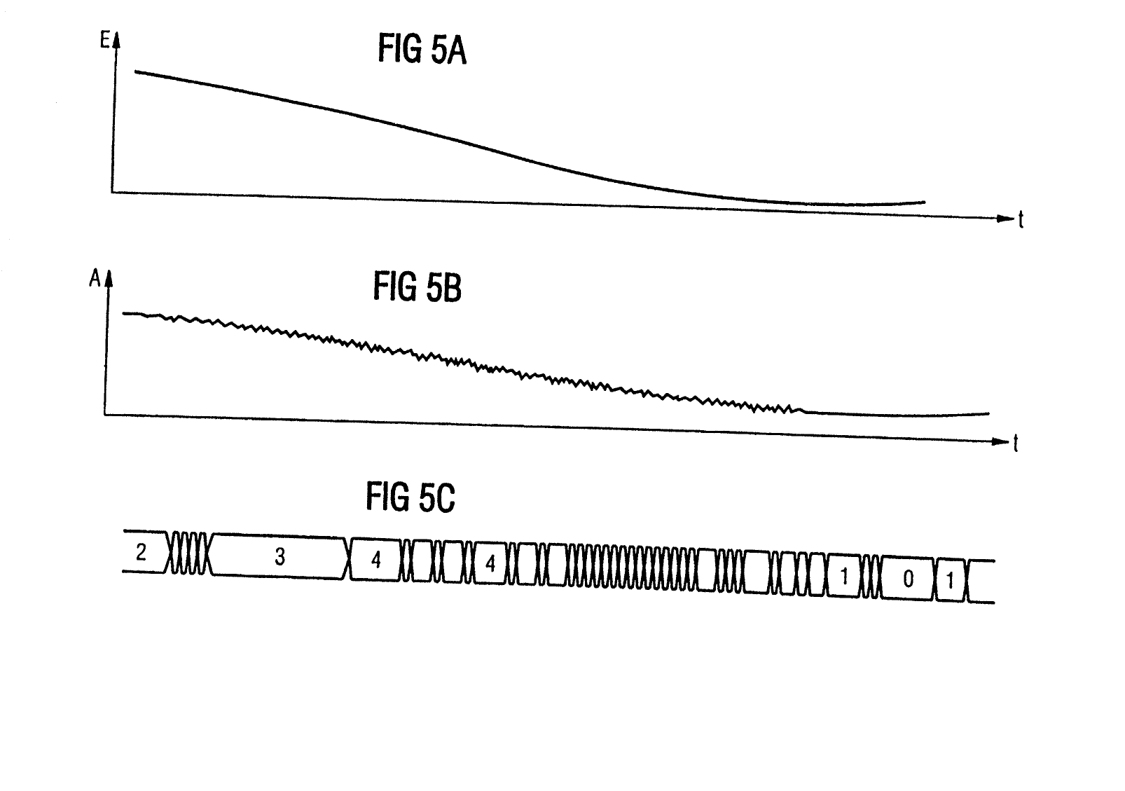

FIGS. 5A-5C shows timing diagrams to explain the method of operation of the inventive tracking analog/digital converter.

FIG. 5A shows an analog input signal, which is applied to the input connection 1 of the inventive analog/digital converter.

FIG. 5B shows the digitized output value at the output connection 20 of the inventive analog/digital converter.

FIG. 5C shows the change to the step size of the counter device 14 as a function of the applied analog input signal.

As can be seen by comparing FIGS. 5a to 5c, the step size of the counter device 14 is increased when the analog input signal E has a steeper signal profile. When the analog input signal E has a flat signal profile, the step size of the counter device 14 is reduced. By way of example, the step size for a steep signal profile is “4”, while the step size of the counter device 14 is “0” around the peak of the sinusoidal signal profile, as is shown in FIG. 5a. The step sizes are in binary steps, so that the step size “4” is 16 times as great as the step size “0”.

I claim:

1. A tracking analog/digital converter, comprising:
a comparison circuit for comparing an analog input signal with an analog comparison signal, said comparison circuit emitting a comparator output signal;
an evaluation circuit for evaluating the converter output signal;
a counter device with an adjustable counter step size for emitting a digital count value; and
a digital/analog converter for converting the digital count value to an analog comparison signal;
said evaluation circuit setting the counter step size as a function of the comparator output signal that has been evaluated;
if the comparator output signal is an essentially constant sequence, said evaluation circuit increases the counter step size; and
if the comparator output signal is an essentially alternating sequence, said evaluation circuit reduces the counter step size.

2. The tracking analog/digital converter according to claim 1, wherein:
said comparison circuit includes a subtractor that subtracts the analog comparison signal from the analog input signal and emits an analog difference signal; and
said comparison circuit includes a comparator that compares the analog difference signal with a reference potential and emits the comparator output signal.

3. The tracking analog/digital converter according to claim 2, wherein the comparator output signal is a binary signal sequence.

4. The tracking analog/digital converter according to claim 1, wherein the comparator output signal is a binary signal sequence.

5. The tracking analog/digital converter according to claim 4, wherein said evaluation circuit has a buffer storage device for storing a data sequence that represents the binary signal sequence.

6. The tracking analog/digital converter according to claim 5, wherein said buffer storage device is a clocked shift register.

7. The tracking analog/digital converter according to claim 5, wherein said evaluation circuit has a logic circuit for logically evaluating the data sequence that is stored in said buffer storage device.

8. The tracking analog/digital converter according to claim 7, wherein:
said evaluation circuit includes a counter step size adjusting device for adjusting the counter step size of said counter device;
said logic circuit supplies a logic evaluation signal to said counter step size adjusting device; and
the counter step size is adjustable as a function of the logic evaluation signal.

9. The tracking analog/digital converter according to claim 8, wherein said counter step size adjusting device is a step-up/step-down counter which, as a function of the logic evaluation signal, performs a function selected from the group consisting of increasing the counter step size, reducing the counter step size, and keeping the counter step size constant.

10. The tracking analog/digital converter according to claim 9, wherein said step-up/step-down counter has an overflow protection circuit.

11. The tracking analog/digital converter according to claim 7, wherein said logic circuit includes logic gates having logic inputs that are connected to said buffer storage device.

12. The tracking analog/digital converter according to claim 1, wherein:
said counter device has a synchronous step-up/step-down counter with an adjustable step size; and
said synchronous step-up/step-down counter includes a plurality of series-connected, controllable counter cells.

13. The tracking analog/digital converter according to claim 12, wherein said counter device has a logic decoding circuit for driving said controllable counter cells as a function of the counter step size.

14. The tracking analog/digital converter according to claim 13, wherein said logic decoding circuit is a thermometer decoding circuit.

15. The tracking analog/digital converter according to claim 13, wherein, as a function of the counter step size that has been set, said logic decoding circuit performs an operation selected from the group consisting of inhibiting said controllable counter cells and allowing said controllable counter cells to count.

16. The tracking analog/digital converter according to claim 1, wherein:
said evaluation circuit has an inhibiting circuit; and
said inhibiting circuit, when the counter step size is changed, inhibits any further change to the counter step size for a predetermined number of clock cycles.
